(19) United States
(12) Patent Application Publication
(10) Pub. No.: US 2026/0275566 A1
(43) Pub. Date: Sep. 17, 2026

(54) SILICON SINGLE CRYSTAL PRODUCTION METHOD AND SILICON SINGLE CRYSTAL PRODUCTION APPARATUS

(71) Applicant: SUMCO Corporation, Tokyo (JP)

(72) Inventors: Hideki SAKAMOTO, Tokyo (JP); Wataru SUGIMURA, Tokyo (JP); Ryusuke YOKOYAMA, Tokyo (JP); Naoki MATSUSHIMA, Tokyo (JP); Takuya YOTSUI, Tokyo (JP)

(73) Assignee: SUMCO Corporation, Tokyo (JP)

(21) Appl. No.: 19/472,308

(22) PCT Filed: Dec. 26, 2023
(86) PCT No.: PCT/JP2023/046676

§ 371 Date: Oct. 3, 2025

(30) Foreign Application Priority Data
Apr. 4, 2023 (JP) 2023-060710

(51) Int. Cl. C30B 15/00; C30B 15/10; C30B 30/04; C30B 35/00

(52) U.S. Cl. CPC C30B 15/007; C30B 15/10; C30B 30/04; C30B 35/002

(57) ABSTRACT

A production method of monocrystalline silicon of pulling up the monocrystalline silicon while applying a horizontal magnetic field to a silicon melt, by using a monocrystalline silicon production apparatus that includes a crucible and a heater having a hollow cylindrical shape and surrounding the crucible. The heater includes first and second heat generating sections having a hollow semi-cylindrical shape and the same heat generation property. The heater is disposed so that, when the heat generating sections generate heat with mutually different heat generation amounts, heating amounts of first and second portions of the crucible are mutually different. The first and second portions are located on both sides across a vertical virtual plane including a center axis of the crucible and a central magnetic field line of the horizontal magnetic field. The method includes performing first heating and producing while the heat generating sections generate heat with the same heat generation amount, and second heating and producing while the heat generating sections generate heat with mutually different heat generation amounts.

### TECHNICAL FIELD

The present invention relates to a production method of monocrystalline silicon and a monocrystalline silicon production apparatus.

### BACKGROUND ART

The MCZ (magnetic field applied Czochralski) method, in which a horizontal magnetic field is applied to a silicon melt, is occasionally used as a production method of monocrystalline silicon. When a horizontal magnetic field is applied to the silicon melt using the MCZ method, a direction of convection in a virtual plane orthogonal to a direction of applying the horizontal magnetic field in the silicon melt becomes sometimes clockwise (hereinafter referred to as a “clockwise vortex mode) and sometimes counterclockwise (hereinafter referred to as “counterclockwise vortex mode”).

The formed convection mode is at random either the clockwise vortex mode or the counterclockwise vortex mode. Accordingly, an oxygen concentration incorporated into monocrystalline silicon varies depending on the convection mode and furnace environments. In order to obtain ingots of monocrystalline silicon having a stable oxygen concentration, it is important to control the convection mode of the silicon melt during pulling up of the ingots of monocrystalline silicon. For this reason, various studies have been made on methods for controlling the convection mode of the silicon melt in a crucible (for instance, see Patent Literature 1).

Patent Literature 1 discloses a method for eliminating variation in oxygen concentration caused by the convection mode, by providing a thermal environment inside the furnace of a production apparatus that is non-axisymmetric with respect to a center axis of the crucible, thereby fixing the convection mode to one of the clockwise vortex mode and the counterclockwise vortex mode.

As a specific method, Patent Literature 1 discloses varying the resistance value of a heater and the thickness of a heat insulation material along a circumferential direction of the crucible.

### CITATION LIST

### Patent Literature(S)

Patent Literature 1: JP 2019-151502 A

### SUMMARY OF THE INVENTION

### Problem(s) to be Solved by the Invention

In the method disclosed in Patent Literature 1, however, the non-axisymmetric thermal environment is achieved by the furnace structure, and therefore the degree of non-axisymmetry cannot be changed during production of monocrystalline silicon.

Thus, in a raw material melting step, for instance, the silicon material may be melted unevenly in the circumferential direction of the crucible. This may cause the solid silicon material floating in the silicon melt to flip over and come into strong contact with a quartz crucible, resulting in damage of the quartz crucible.

An object of the invention is to provide a production method of monocrystalline silicon and a monocrystalline silicon production apparatus capable of inhibiting the occurrence of defects during the production and the variation in oxygen concentration between ingots of monocrystalline silicon.

### Means for Solving the Problem(s)

A production method of monocrystalline silicon according an aspect of the invention is a production method of monocrystalline silicon of pulling up the monocrystalline silicon while applying a horizontal magnetic field to a silicon melt, by using a monocrystalline silicon production apparatus, the monocrystalline silicon production apparatus including a crucible configured to hold the silicon melt, and a heater having a hollow cylindrical shape and surrounding the crucible, the heater including a first heat generating section and a second heat generating section each having a hollow semi-cylindrical shape, the first and second heat generating sections having an identical heat generation property, the heater being disposed so that, when the first and second heat generating sections generate heat with heat generation amounts different from each other, a heating amount of a first portion of the crucible and a heating amount of a second portion of the crucible are different from each other, the first portion and the second portion being located on both sides with respect to a vertical virtual plane that includes a center axis of the crucible and a central magnetic field line of the horizontal magnetic field, the production method including: performing first heating and producing while the first heat generating section and the second heat generating section generate heat with an identical heat generation amount; and performing second heating and producing while the first heat generating section and the second heat generating section generate heat with heat generation amounts different from each other.

In the production method of the monocrystalline silicon according the aspect of the invention, it is preferable that the monocrystalline silicon production apparatus further includes a first power source and a second power source, a first power supply path through which electric power of the first power source is supplied to the first heat generating section, and a second power supply path through which electric power of the second power source is supplied to the second heat generating section, the first heating and producing is performed while the first power source and the second power source are controlled to cause the first heat generating section and the second heat generating section to generate heat with an identical heat generation amount, and the second heating and producing is performed while the first power source and the second power source are controlled to cause the first heat generating section and the second heat generating section to generate heat with heat generation amounts different from each other.

In the production method of the monocrystalline silicon according the aspect of the invention, it is preferable that the monocrystalline silicon production apparatus further includes a bypass supply path connecting the first power supply path to the second power supply path, and a flow regulator provided in the bypass supply path and configured to supply electric power only in a direction from the first power supply path to the second power supply path, the first heating and producing is performed while the first power source and the second power source are controlled to supply electric power from the first power source and not from the second power source, and the second heating and producing is performed while the first power source and the second power source are controlled to supply electric power from the first power source and the second power source.

Preferably, the production method of the monocrystalline silicon according the aspect of the invention further includes: generating the silicon melt by melting a silicon material in the crucible; starting applying the horizontal magnetic field to the silicon melt; checking that a convection direction of the silicon melt in a virtual plane is fixed to one direction, the virtual plane being orthogonal to the central magnetic field line; performing first growing in which a neck and a shoulder are grown by bringing a seed crystal into contact with the silicon melt and then pulling up the seed crystal; and performing second growing in which a straight body and a tail are grown by pulling up the seed crystal, in which the generating the silicon melt and the second growing are performed as the first heating and producing, and the starting applying the horizontal magnetic field, the checking, and the first growing are performed as the second heating and producing.

Preferably, the production method of the monocrystalline silicon according the aspect of the invention further includes: generating the silicon melt by melting a silicon material in the crucible; starting applying the horizontal magnetic field to the silicon melt; checking that a convection direction of the silicon melt in a virtual plane is fixed to one direction, the virtual plane being orthogonal to the central magnetic field line; performing first growing in which a neck and a shoulder are grown by bringing a seed crystal into contact with the silicon melt and then pulling up the seed crystal; performing reversal determination; and performing second growing in which a straight body and a tail are grown by pulling up the seed crystal, in which the generating the silicon melt is performed as the first heating and producing, the starting applying the horizontal magnetic field, the checking, and the first growing are performed as the second heating and producing, and in the reversal determination as to the second growing to be performed as the first heating and producing based on a pull-up condition of the monocrystalline silicon, the second growing is performed as the second heating and producing when it is determined that the convection direction is likely to reverse, and the second growing is performed as the first heating and producing when it is determined that the convection direction is not likely to reverse.

In the production method of the monocrystalline silicon according the aspect of the invention, it is preferable that the first heat generating section and the second heat generating section are disposed so that the first and second heat generating sections have respective highest temperature regions overlapping a horizontal virtual line in planar view in planar view, the horizontal virtual line being orthogonal to the vertical virtual plane and including the center axis of the crucible.

A monocrystalline silicon production apparatus according to another aspect of the invention includes: a crucible configured to hold the silicon melt; a heater having a hollow cylindrical shape and surrounding the crucible; and a power supply section configured to supply electric power to the heater, in which the heater includes a first heat generating section and a second heat generating section each having a hollow semi-cylindrical shape, the first and second heat generating sections having an identical heat generation property, and the power supply section includes a first power source and a second power source, a first power supply path through which electric power of the first power source is supplied to the first heat generating section, and a second power supply path through which electric power of the second power source is supplied to the second heat generating section.

In the monocrystalline silicon production apparatus according to the other aspect of the invention, it is preferable that the power supply section further includes a bypass supply path connecting the first power supply path to the second power supply path, and a flow regulator provided in the bypass supply path and configured to supply electric power only in a direction from the first power supply path to the second power supply path.

Preferably, the monocrystalline silicon production apparatus according to the other aspect of the invention further includes: a controller configured to control producing, the monocrystalline silicon being pulled up in the producing, in which the producing includes performing first heating and producing while the first power source and the second power source are controlled to cause the first heat generating section and the second heat generating section to generate heat with an identical heat generation amount, and performing second heating and producing while the first power source and the second power source are controlled to cause the first heat generating section and the second heat generating section to generate heat with heat generation amounts different from each other.

Preferably, the monocrystalline silicon production apparatus according to the other aspect of the invention further includes: a controller configured to control producing, the monocrystalline silicon being pulled up in the producing, in which the producing includes performing first heating and producing while the first power source and the second power source are controlled to supply electric power from the first power source and not from the second power source, and performing second heating and producing while the first power source and the second power source are controlled to supply electric power from the first power source and the second power source.

In the monocrystalline silicon production apparatus according to the other aspect of the invention, it is preferable that the producing further includes generating the silicon melt by melting a silicon material in the crucible, starting applying the horizontal magnetic field to the silicon melt, checking that a convection direction of the silicon melt in a virtual plane is fixed to one direction, the virtual plane being orthogonal to a central magnetic field line of the horizontal magnetic field, performing first growing in which a neck and a shoulder are grown by bringing a seed crystal into contact with the silicon melt and then pulling up the seed crystal, and performing second growing in which a straight body and a tail are grown by pulling up the seed crystal, and the controller is configured to perform the generating the silicon melt and the second growing as the first heating and producing, and to perform the starting applying the horizontal magnetic field, the checking, and the first growing as the second heating and producing.

In the monocrystalline silicon production apparatus according to the other aspect of the invention, it is preferable that the producing further includes generating the silicon melt by melting a silicon material in the crucible, starting applying the horizontal magnetic field to the silicon melt, checking that a convection direction of the silicon melt in a virtual plane is fixed to one direction, the virtual plane being orthogonal to a central magnetic field line of the horizontal magnetic field, performing first growing in which a neck and a shoulder are grown by bringing a seed crystal into contact with the silicon melt and then pulling up the seed crystal, performing reversal determination, and performing second growing in which a straight body and a tail are grown by pulling up the seed crystal, and the controller is configured to perform the generating the silicon melt as the first heating and producing, to perform the starting applying the horizontal magnetic field, the checking, and the first growing as the second heating and producing, and in the reversal determination as to the second growing to be performed as the first heating and producing based on a pull-up condition of the monocrystalline silicon, to perform the second growing as the second heating and producing when it is determined that the convection direction is likely to reverse, and to perform the second growing as the first heating and producing when it is determined that the convection direction is not likely to reverse.

In the monocrystalline silicon production apparatus according to the other aspect of the invention, it is preferable that the first heat generating section and the second heat generating section are disposed so that the first and second heat generating sections have respective highest temperature regions overlapping a horizontal virtual line in planar view, the horizontal virtual line being orthogonal to a vertical virtual plane and including a center axis of the crucible, the vertical virtual plane including the center axis of the crucible and a central magnetic field line of the horizontal magnetic field.

### BRIEF DESCRIPTION OF DRAWINGS

FIG. 1 is a vertical cross-sectional view of a schematic configuration of a monocrystalline silicon production apparatus according to a first exemplary embodiment and a second exemplary embodiment.

FIG. 2 is a schematic plan view of a heater and a magnetic-field applying section according to the first and second exemplary embodiments.

FIG. 3 is a perspective view of the heater according to the first and second exemplary embodiments.

FIG. 4 is an equivalent circuit diagram of the heater and a power supply section according to the first exemplary embodiment.

FIG. 5 is a block diagram of relevant parts of the monocrystalline silicon production apparatus according to the first and second embodiments.

FIG. 6 is a flowchart of a production method of monocrystalline silicon according to the first and second exemplary embodiments.

FIG. 7 is an equivalent circuit diagram of the heater and a power supply section according to the second exemplary embodiment.

### DESCRIPTION OF EMBODIMENT(S)

### First Exemplary Embodiment

### Configuration of Monocrystalline Silicon Production Apparatus

First, the configuration of a monocrystalline silicon production apparatus according to a first exemplary embodiment of the invention will be described.

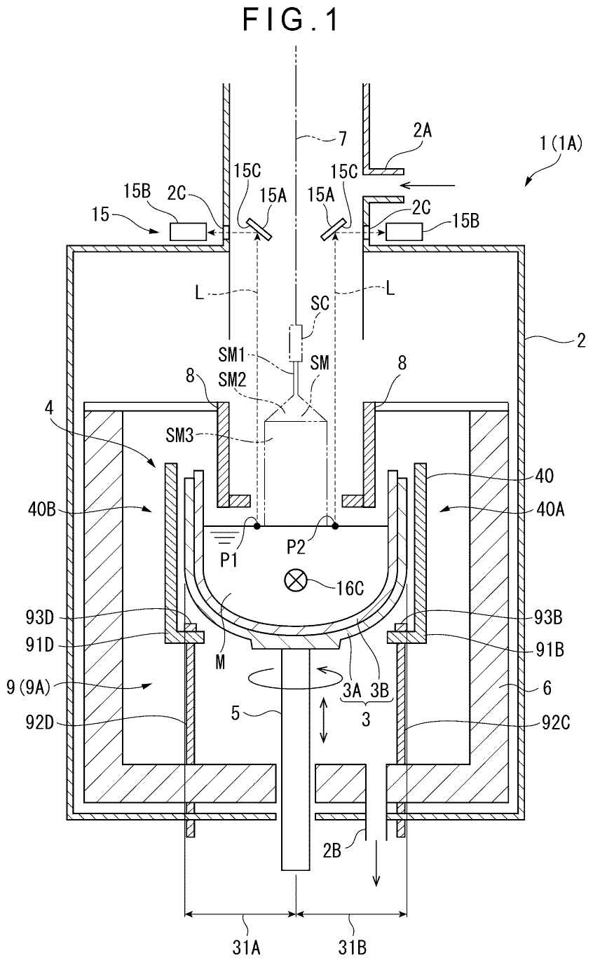

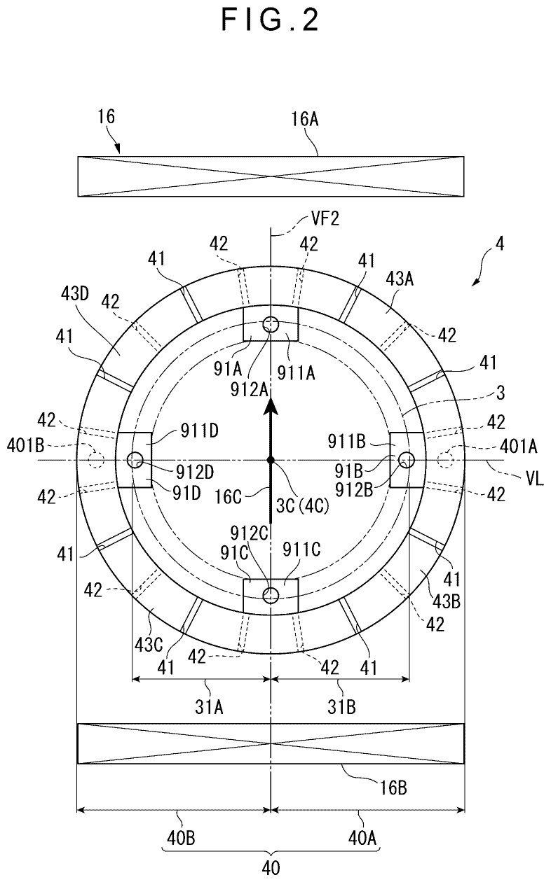

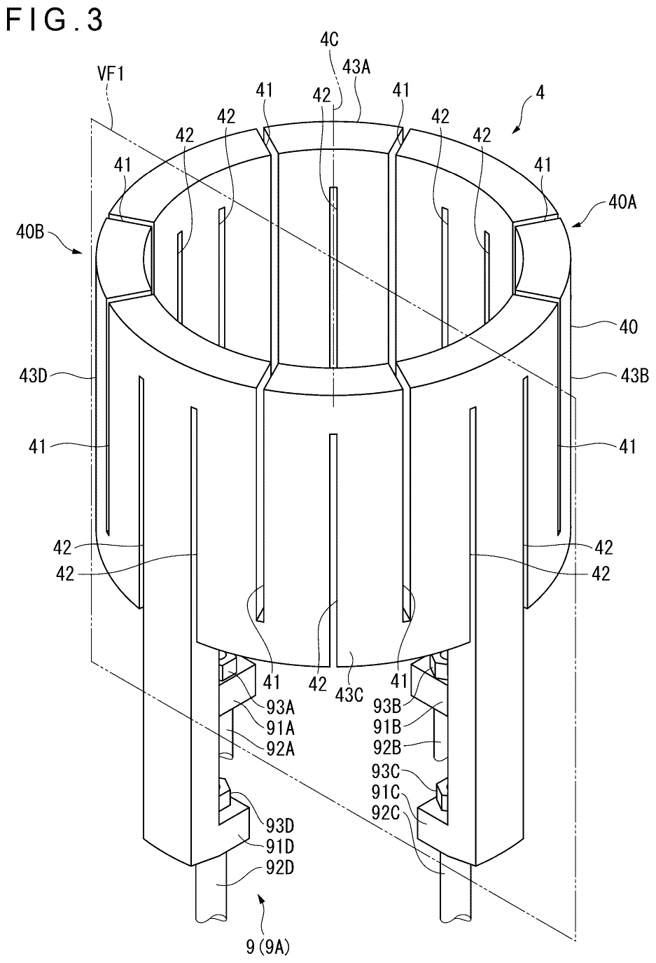

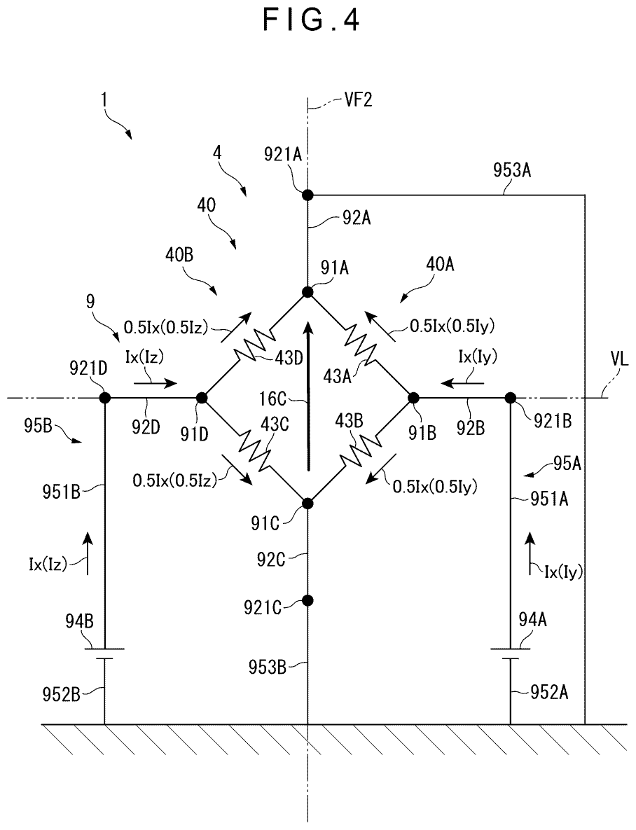

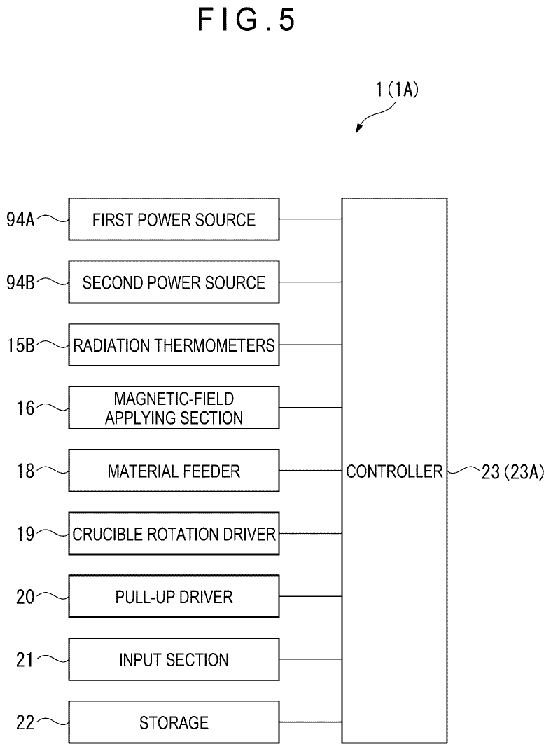

FIG. 1 is a vertical cross-sectional view of a schematic configuration of the monocrystalline silicon production apparatus. FIG. 2 is a schematic plan view of a heater and a magnetic-field applying section. FIG. 3 is a perspective view of the heater. FIG. 4 is an equivalent circuit diagram of the heater and a power supply section. FIG. 5 is a block diagram of relevant parts of the monocrystalline silicon production apparatus.

A monocrystalline silicon production apparatus 1 illustrated in FIG. 1 is an apparatus for producing monocrystalline silicon SM by the MCZ method, in which the monocrystalline silicon SM including a neck SM1, a shoulder SM2, a straight body SM3, and a tail (not illustrated) is pulled up while a horizontal magnetic field is applied to a silicon melt M. The monocrystalline silicon production apparatus 1 includes a chamber 2 forming an outer shell, a crucible 3 disposed in a central portion of the chamber 2, a heater 4 disposed around the crucible 3, and a temperature measurement section 15.

The crucible 3 has a double-layered structure including a graphite crucible 3A on an outer side and a quartz crucible 3B on an inner side, and the silicon melt M is contained in the quartz crucible 3B. The graphite crucible 3A and the quartz crucible 3B are each a bottomed hollow cylindrical container, and each have a circular shape in planar view when viewed from vertically above. The crucible 3 is fixed to an upper end of a support shaft 5 that is rotatable and movable upward and downward.

The heater 4 is a graphite heater having a substantially hollow cylindrical shape and disposed around the crucible 3. A heat insulation material 6 having a hollow cylindrical shape is provided on an outer side of the heater 4 along an inner surface of the chamber 2.

Above the crucible 3, a pull-up shaft 7 is disposed coaxially with the support shaft 5. The pull-up shaft 7 is formed of, for instance, a wire. A seed crystal SC is attached to a lower end of the pull-up shaft 7.

Inside the chamber 2, a heat shield 8 having a hollow cylindrical shape is disposed above the silicon melt M in the crucible 3 to surround the growing monocrystalline silicon SM.

The heat shield 8 shields the growing monocrystalline silicon SM from radiation heat from the silicon melt M, a side wall of the crucible 3 and the heater, thereby inhibiting a temperature rise of the monocrystalline silicon SM.

A gas inlet 2A, through which an inert gas such as argon gas is introduced into the chamber 2, is provided at an upper part of the chamber 2. An exhaust outlet 2B, through which the gas in the chamber 2 is sucked and discharged when a vacuum pump (not illustrated) is driven, is provided at a lower part of the chamber 2.

The temperature measurement section 15 measures temperatures at a first measurement point P1 and a second measurement point P2. A position of each of the first measurement point P1 and the second measurement point P2 in a radial direction is set between an outer circumferential surface of the monocrystalline silicon SM to be grown and an inner circumferential surface of an opening of the heat shield 8. As will be described later, by measuring the temperatures at the first measurement point P1 and the second measurement point P2, a convection mode of the silicon melt M can be checked. For instance, when a convection direction of the silicon melt M is fixed to a clockwise direction in FIG. 1 by the heater 4 heating the silicon melt M, i.e., the convection mode of the silicon melt M is the clockwise vortex mode, the temperature measured at the first measurement point P1 is higher than that at the second measurement point P2. When the convection direction of the silicon melt M is fixed to a counterclockwise direction by the heater 4 heating the silicon melt M, i.e., the convection mode is the counterclockwise vortex mode, the temperature measured at the first measurement point P1 is lower than that at the second measurement point P2.

The temperature measurement section 15 includes a pair of reflectors 15A and a pair of radiation thermometers 15B.

The reflectors 15A are provided inside the chamber 2. The reflectors 15A are preferably provided with an angle between a reflection surface 15C of each of the reflectors 15A and a horizontal plane being in a range from 40 degrees to 50 degrees.

The radiation thermometers 15B are provided outside the chamber 2. The radiation thermometers 15B receive radiation light L incident through quartz windows 2C (see FIG. 1) provided at the chamber 2, and measure the temperatures at the first measurement point P1 and the second measurement point P2 in a non-contact manner.

As illustrated in FIG. 2, the monocrystalline silicon production apparatus 1 further includes a magnetic-field applying section 16.

The magnetic-field applying section 16 includes a first magnetic body 16A and a second magnetic body 16B, each in a form of an electromagnetic coil. The first magnetic body 16A and the second magnetic body 16B are provided outside the chamber 2 so as to face each other with the crucible 3 therebetween. The magnetic-field applying section 16 applies a horizontal magnetic field so that, in planar view, a central magnetic field line 16C passing through a coil center axis intersects a center axis 3C of the crucible 3 (hereinafter, occasionally referred to as the “crucible center axis 3C”) and is directed toward the first magnetic body 16A from the second magnetic body 16B (i.e., in an upward direction indicated by an arrow representing the central magnetic field line 16C in FIG. 2, which corresponds to a direction from the front to the back of the sheet of FIG. 1).

The heater 4 is disposed with a center axis 4C thereof (hereinafter referred to as “heater center axis 4C”) located coaxially with the crucible center axis 3C. The heat insulation material 6 is disposed with a center axis thereof located coaxially with the crucible center axis 3C. In other words, the crucible 3, heater 4, and heat insulation material 6 are disposed so that a gap between the crucible 3 and the heater 4 and a gap between the heater 4 and the heat insulation material 6 are each uniform along a circumferential direction of the crucible 3. With this arrangement of the crucible 3, heater 4, and heat insulation material 6, when the heater 4 generates heat uniformly along the circumferential direction, a heating distribution by the heater 4 and a heat extraction distribution by the heat insulation material 6 are each uniform along the circumferential direction of the crucible 3.

As illustrated in FIGS. 2 and 3, the heater 4 includes a heat generating section 40 in a form of a graphite heater having a hollow cylindrical shape. The heat generating section 40 has a uniform thickness throughout a circumferential direction thereof. The heat generating section 40 has a plurality of upper slits 41 extending downward from an upper end of the heat generating section 40 and a plurality of lower slits 42 extending upward from a lower end thereof. The upper slits 41 and lower slits 42 are alternately disposed in the circumferential direction. The upper slits 41 and the lower slits 42 are equal to each other in width dimension as well as in cut depth in a vertical direction. Further, the upper slit 41 and the lower slit 42 are equally spaced over the entire circumference of the heater 4.

The heat generating section 40 includes a first heat generating section 40A and a second heat generating section 40B. The first heat generating section 40A having a hollow semi-cylindrical shape is located on one side of a first vertical virtual plane VF1 that includes the heater center axis 4C. The second heat generating section 40B having a hollow semi-cylindrical shape is located on the other side and has the same heat generation property as the first heat generating section 40A. The same heat generation property means that when electric power of a same magnitude is supplied, a same part generates a same heat generation amount.

The first heat generating section 40A and the second heat generating section 40B are equal to each other in total number of the upper slits 41 and the lower slits 42. In the exemplary embodiment, the first and second heat generating sections 40A and 40B each have four upper slits 41 and six lower slits 42, and thus the total number of the upper slits 41 and the lower slits 42 is ten.

The monocrystalline silicon production apparatus 1 includes a power supply section 9 for supplying electric power to the heat generating section 40. The power supply section 9 includes a first terminal 91A, a second terminal 91B, a third terminal 91C and a fourth terminal 91D, a first support electrode 92A, a second support electrode 92B, a third support electrode 92C and a fourth support electrode 92D, and four nuts 93A, 93B, 93C and 93D. The first to fourth terminals 91A to 91D are disposed at 90-degree intervals along the circumferential direction of the heat generating section 40.

The first to fourth terminals 91A to 91D each extend downward from a lower end of a portion partitioned by two lower slits 42, and are each provided integrally with the heat generating section 40. Further, the first to fourth terminals 91A to 91D include connecting portions 911A to 911D, respectively, that are each bent inward at a right angle from a lower end of each terminal. The connecting portions 911A to 911D have through holes 912A to 912D, respectively.

In other words, the heater 4 includes a graphite heater that is formed by integrally molding the heat generating section 40 having a hollow cylindrical shape that is a heater element and the first to fourth terminals 91A to 91D that are heater foots.

The heat generating section 40 is partitioned into a first curve portion 43A, a second curve portion 43B, a third curve portion 43C, and a fourth curve portion 43D each having a zigzag shape with the upper slits 41 and the lower slits 42 provided therein. The first to fourth curve portions 43A to 43D configure four heater elements.

Specifically, two upper slits 41 and three lower slits 42 are alternately provided between the first terminal 91A and the second terminal 91B to provide the first curve portion 43A. Similarly, two upper slits 41 and three lower slits 42 are alternately provided between the second terminal 91B and the third terminal 91C to provide the second curve portion 43B.

Two upper slits 41 and three lower slits 42 are alternately provided between the third terminal 91C and the fourth terminal 91D to provide the third curve portion 43C. Two upper slits 41 and three lower slits 42 are alternately provided between the fourth terminal 91D and the first terminal 91A to provide the fourth curve portion 43D.

Thus, the first to fourth curve portions 43A to 43D with the same shape have the same resistance value. Therefore, when the magnitude of current flowing through the first to fourth curve portions 43A to 43D is the same, the first to fourth curve portions 43A to 43D generate heat with the same heat generation amount.

The first heat generating section 40A includes the first curve portion 43A and the second curve portion 43B, and the second heat generating section 40B includes the third curve portion 43C and the fourth curve portion 43D.

As illustrated in FIG. 2, the heater 4 is disposed so that the heater center axis 4C is located coaxially with the crucible center axis 3C, and the first heat generating section 40A and the second heat generating section 40B are face-symmetrical with respect to a second vertical virtual plane VF2 that includes the crucible center axis 3C and the central magnetic field line 16C. In other words, the heater 4 is disposed so that the second vertical virtual plane VF2 coincides with the first vertical virtual plane VF1 illustrated in FIG. 3.

It can also be said that the heater 4 is disposed so that the first heat generating section 40A and the second heat generating section 40B are twofold symmetrical with respect to the crucible center axis 3C.

Further, it can also be said that the heater 4 is disposed so that, when the first heat generating section 40A and the second heat generating section 40B generate heat with heat generation amounts different from each other, the heating amounts for a first portion 31A and a second portion 31B of the crucible 3 are different from each other, the first portion 31A and the second portion 31B being located on either side with respect to the second vertical virtual plane VF2 that includes the crucible center axis 3C and the central magnetic field line 16C.

Furthermore, in planar view, central regions of the first and second heat generating sections 40A and 40B are highest temperature regions 401A and 401B, respectively. It can also be said that the heater 4 is disposed so that the highest temperature regions 401A and 401B of the first and second heat generating sections 40A and 40B overlap in planar view a horizontal virtual line VL that is orthogonal to the second vertical virtual plane VF2 and includes the crucible center axis 3C. The reason why the central regions of the first and second heat generating sections 40A and 40B are the highest temperature regions 401A and 401B is that the regions where the current flows in the first and second heat generating sections 40A and 40B have the same heat generation amount, but heat transfer causes regions farthest from either end of each of the first and second heat generating sections 40A and 40B to have the highest temperature.

As illustrated in FIG. 3, the first to fourth support electrodes 92A to 92D are rod-shaped electrodes made of carbon having conductivity. Each of the first to fourth support electrodes 92A to 92D has one end inserted through the corresponding one of the through holes 912A to 912D of the respective terminals 91A to 91D, and each of the nuts 93A to 93D made of carbon is screwed onto a male thread formed at the corresponding end. Thus, the first to fourth support electrodes 92A to 92D are electrically connected to the terminals 91A to 91D, respectively, and support the heater 4.

As illustrated in FIG. 4, the power supply section 9 includes a first power source 94A and a second power source 94B, a first power supply path 95A through which electric power of the first power source 94A is supplied to the first heat generating section 40A, and a second power supply path 95B through which electric power of the second power source 94B is supplied to the second heat generating section 40B.

At least one of the first power source 94A or the second power source 94B is capable of changing the supply amount of electric power.

The first power supply path 95A includes the second support electrode 92B, and a first anode wiring 951A connecting the other end 921B of the second support electrode 92B to an anode of the first power source 94A.

The second power supply path 95B includes the fourth support electrode 92D, and a second anode wiring 951B connecting the other end 921D of the fourth support electrode 92D to an anode of the second power source 94B.

Cathodes of the first power source 94A and the second power source 94B are grounded by a grounding wiring 952A and a grounding wiring 952B, respectively. The other end 921A of the first support electrode 92A and the other end 921C of the third support electrode 92C are grounded by a grounding wiring 953A and a grounding wiring 953B, respectively.

With the configuration of the heater 4 and the power supply section 9 as illustrated in FIG. 4, when a current with a current value Ix flows from the first power source 94A and the second power source 94B, a current with a current value 0.5 Ix flows through the first to fourth curve portions 43A to 43D. As described above, the first to fourth curve portions 43A to 43D have the same resistance value. Therefore, when the current with the same current value Ix flows from the first power source 94A and the second power source 94B, that is, when the electric power of the same magnitude is supplied, the first heat generating section 40A and the second heat generating section 40B generate heat with the same heat generation amount.

In contrast, when a current with a current value Iy flows from the first power source 94A and a current with a current value Iz different from the current value Iy flows from the second power source 94B, that is, when the electric power supplied from the first power source 94A has the magnitude different from that supplied from the second power source 94B, a current with a current value 0.5 Iy flows through the first and second curve portions 43A and 43B, and a current with a current value 0.5 Iz flows through the third and fourth curve portions 43C and 43D. Thus, the first and second heat generating sections 40A and 40B generate heat with heat generation amounts different from each other.

Hereinafter, occasionally, a mode for causing the first and second heat generating sections 40A and 40B to generate heat with the same heat generation amount is referred to as a “uniform heating mode,” and a mode for causing the first and second heat generating sections 40A and 40B to generate heat with mutually different heat generation amounts is referred to as a “non-uniform heating mode.” In FIG. 4, among codes attached to arrows indicating the current, the codes outside parentheses represent the current values in the uniform heating mode, and the codes inside the parentheses represent the current values in the non-uniform heating mode. In the non-uniform heating mode, the current value of the current flowing from one of the first power source 94A and the second power source 94B may be the same as the current value in the uniform heating mode, and the current value of the current flowing from each of the first power source 94A and the second power source 94B may be different from the current value in the uniform heating mode.

When the crucible 3 is heated in the uniform heating mode, the silicon melt M in the crucible 3 is uniformly heated over the entire circumference region of the crucible 3.

In this case, the convection occurs in the silicon melt M that rises near the side surface of the crucible 3 and descends near the center. In this state, the position of a downward flow changes randomly and, for instance, deviates from the center of crucible 3 due to instable convection. Then, when a horizontal magnetic field is applied to the silicon melt M, the rotation of the downward flow in the circumferential direction of the crucible 3 is gradually restrained, and eventually the convection direction in a virtual plane orthogonal to an applied direction of the horizontal magnetic field is fixed.

As described above, when the crucible 3 is heated in the uniform heating mode, the horizontal magnetic field is applied while the position of the downward flow is changing randomly. The convection mode thus becomes either the clockwise vortex mode or the counterclockwise vortex mode depending on the timing of the application.

On the other hand, when the crucible 3 is heated in the non-uniform heating mode, the silicon melt M in the crucible 3 is heated so that the temperature of a part of the silicon melt M located near the first heat generating section 40A differs from that of another part located near the second heat generating section 40B.

For instance, when the second heat generating section 40B located on a left side of the crucible 3 generates heat with a larger heat generation amount than the first heat generating section 40A located on a right side, an upward flow is stably generated in the silicon melt M on the left side in the crucible 3, and a downward flow is stably generated in the silicon melt M on the right side in the crucible 3, and the position of the downward flow does not change randomly unlike a case where the first and second heat generating sections 40A and 40B generate heat with the same heat generation amount. When a horizontal magnetic field is applied to the silicon melt M in this state, irrespective of the timing of the application, the convection is fixed in a clockwise direction to be in the clockwise vortex mode. In particular, since the maximum temperature region 401A of the first heat generating section 40A overlaps the horizontal virtual line VL in planar view, a horizontal magnetic field is applied while a virtual line connecting a position where the upward flow is strongest to a position where the downward flow is strongest is almost orthogonal to a generation position of the central magnetic field line 16C. The clockwise vortex mode can thus be generated stably.

In order to generate the clockwise vortex mode with a high probability irrespective of the timing of applying a horizontal magnetic field, an output power deviation Δ calculated by a formula (1) below is preferably 4.0% or more, more preferably 5.0% or more.

$$Δ ( \% ) = ( Q 1 / Q 2 - 1 ) \times 100 \qquad ( 1 )$$

Q1: Output power of the first heat generating section 40A
Q2: Output power of the second heat generating section 40B

Here, in order to inhibit variation in oxygen concentration between ingots of the monocrystalline silicon SM, it is necessary to fix the convection direction of the silicon melt M to one direction, and therefore the crucible 3 is preferably heated in the non-uniform heating mode.

However, if the straight body SM3 of the monocrystalline silicon SM is grown in a thermal environment in the chamber 2 that is non-axisymmetric with respect to the crucible center axis 3C in the non-uniform heating mode, a diameter variation of the straight body SM3 may be larger. If a pull-up speed is controlled to inhibit the diameter variation, pull-up speed variation may be larger.

Thus, it is believed that the diameter variation of the straight body SM3 and the pull-up speed variation can be inhibited by heating the crucible 3 in the non-uniform heating mode before pulling up the straight body SM3 to fix the convection of the silicon melt M in one direction, and then shifting the heating mode of the crucible 3 to the uniform heating mode and pulling up the straight body SM3.

However, as described above, when the crucible 3 is heated in the uniform heating mode, the position of the downward flow changes randomly, which may cause a reversal of the convection direction during the pull-up of the straight body SM3. If such a reversal of the convection direction occurs, the concentration of oxygen taken into the straight body SM3 may vary. In addition, it is believed that whether or not the reversal of the convection direction occurs depends on pull-up conditions of the monocrystalline silicon SM.

It is thus preferable to check in advance whether or not the convection direction is likely to reverse when the non-uniform heating mode is shifted to the uniform heating mode after fixing the convection direction in the non-uniform heating mode, and to determine according to the results of the check whether or not the non-uniform heating mode is to be shifted to the uniform heating mode after fixing the convection mode.

As illustrated in FIG. 5, the monocrystalline silicon production apparatus 1 further includes a material feeder 18, a crucible rotation driver 19, a pull-up driver 20, an input section 21, a storage 22, and a controller 23. The first power source 94A, the second power source 94B, the radiation thermometers 15B, the magnetic-field applying section 16, the material feeder 18, the crucible rotation driver 19, the pull-up driver 20, the input section 21, and the storage 22 are connected to the controller 23 so that various information can be sent to and received from the controller 23.

The first power source 94A and the second power source 94B supply electric power of a same magnitude or different magnitudes to the first heat generating section 40A and the second heat generating section 40B, respectively, under the control of the controller 23.

The radiation thermometers 15B each output signals corresponding to measurement results to the controller 23.

The magnetic-field applying section 16 applies a horizontal magnetic field of a predetermined intensity to the silicon melt M under the control of the controller 23.

The material feeder 18 feeds a silicon material into the crucible 3 under the control of the controller 23. An operator may feed the silicon material into the crucible 3 without providing the material feeder 18 at the monocrystalline silicon production apparatus 1.

The crucible rotation driver 19 rotates the crucible 3 at a predetermined speed in a predetermined direction under the control of the controller 23.

The pull-up driver 20 raises and lowers the pull-up shaft 7 under the control of the controller 23. In addition, the pull-up driver 20 rotates the pull-up shaft 7 at a predetermined speed in a direction opposite to or same as the rotation direction of the support shaft 5 under the control of the controller 23.

The input section 21 is, for instance, provided in a form of a touch panel or a physical button. The input section 21, which is used for input operations of various settings, outputs signals corresponding to the input operations to the controller 23.

The storage 22 is provided in a form of a well-known storage device such as a hard disk drive (HDD). The storage 22 stores various information necessary for pull-up control of the monocrystalline silicon SM and information for convection reversal determination.

The information for convection reversal determination includes, for each pull-up condition of the monocrystalline silicon SM and for each monocrystalline silicon production apparatus 1, details representing whether or not the convection direction is likely to reverse when the convection mode of the silicon melt M is fixed in the non-uniform heating mode and then the convection mode is shifted to the uniform heating mode. The presence or absence of convection reversal likelihood for each pull-up condition may be checked through experiments using the monocrystalline silicon production apparatus 1 or through production of the monocrystalline silicon SM, or alternatively may be checked through simulation.

The controller 23 includes a CPU (central processing unit). The controller 23 controls the pull-up of the monocrystalline silicon SM by the CPU running a program stored in the storage 22.

### Production Method of Monocrystalline Silicon

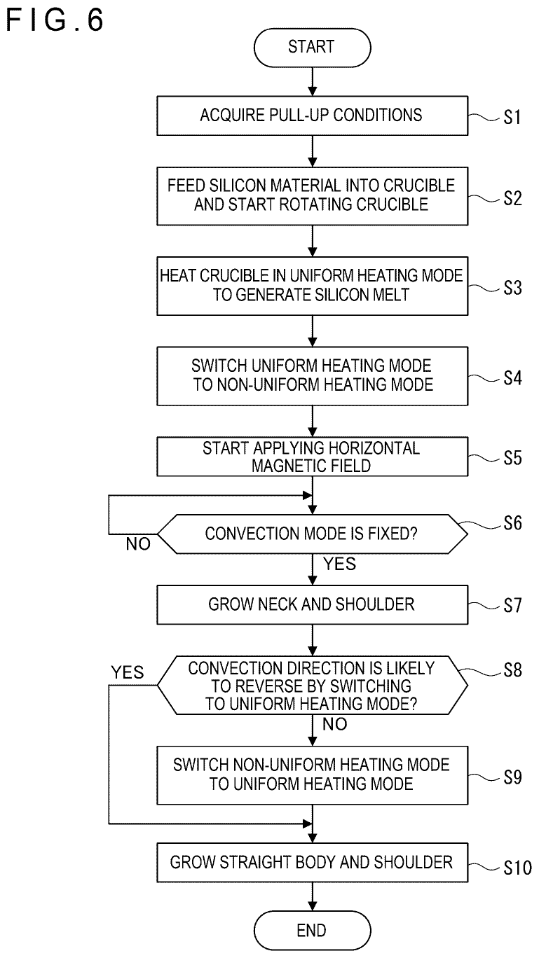

A production method of the monocrystalline silicon SM using the monocrystalline silicon production apparatus 1 will be described below. FIG. 6 is a flowchart of the production method of the monocrystalline silicon.

The first exemplary embodiment exemplifies that the second heat generating section 40B generates heat with a larger heat generation amount than the first heat generating section 40A in the non-uniform heating mode. The heat generation amounts of the first and second heat generating sections 40A and 40B in the uniform heating mode may be the same as or different from the heat generation amount of the first heat generating section 40A or the second heat generating section 40B in the non-uniform heating mode.

First, an operator operates the input section 21 to input the pull-up conditions for the monocrystalline silicon SM to be produced.

The controller 23 acquires the input pull-up conditions (Step S1), as illustrated in FIG. 6.

Thereafter, the controller 23 performs a production process of the monocrystalline silicon SM based on the acquired pull-up conditions.

Specifically, while maintaining an inert atmosphere under reduced pressure inside the chamber 2, turning off the heater 4 (i.e., not supplying electric power to the heater 4) and not applying a horizontal magnetic field, the controller 23 controls the material feeder 18 to feed the silicon material into the crucible 3 and then controls the crucible rotation driver 19 to rotate the crucible 3 in one direction (Step S2). If the material feeder 18 is not provided at the monocrystalline silicon production apparatus 1, the operator feeds the silicon material into the crucible 3.

Subsequently, the controller 23 controls the first and second power sources 94A and 94B to heat the crucible 3 in the uniform heating mode using the first and second heat generating sections 40A and 40B of the heater 4, thereby melting the silicon material to generate the silicon melt M (Step S3: silicon melt generating step). In Step S3, the crucible 3 is heated uniformly over the entire circumference region of the crucible 3. Therefore, the silicon material can be melted uniformly along the circumferential direction of the crucible 3, and the solid silicon material floating in the silicon melt M can be inhibited from flipping over and coming into contact with the quartz crucible 3B. As a result, damage to the quartz crucible 3B can be prevented.

When all the silicon material is melted, the position of the downward flow generated in the silicon melt M changes randomly.

At the timing when all the silicon material is melted, the controller 23 controls the first and second power sources 94A and 94B to switch the uniform heating mode to the non-uniform heating mode (Step S4). After a predetermined time has elapsed from Step S4, the temperature of a left part of the silicon melt M heated by the second heat generating section 40B becomes higher than the temperature of a right part heated by the first heat generating section 40A, and an upward flow is stably generated on the left side in the crucible 3 and also a downward flow is stably generated on the right side in the crucible 3.

Thereafter, the controller 23 controls the magnetic-field applying section 16 to start applying a horizontal magnetic field to the silicon melt M (Step S5: magnetic-field applying step). When the horizontal magnetic field of a predetermined intensity is applied to the silicon melt M through Step S5, the convection is fixed in a clockwise direction to be in the clockwise vortex mode.

Subsequently, the controller 23 checks whether or not the convection mode of the silicon melt M is fixed to the clockwise vortex mode based on the signals corresponding to the measurement results from the radiation thermometers 15B (Step S6: convection direction checking step).

When determining that the convection mode is not fixed to the clockwise vortex mode (Step S6: NO), the controller 23 performs Step S6 again after a predetermined time has elapsed.

On the other hand, when determining that the convection mode is fixed to the clockwise vortex mode (Step S6: YES), the controller 23 controls the pull-up driver 20 to grow the neck SM1 and the shoulder SM2 while continuing heating in the non-uniform heating mode and applying a horizontal magnetic field (Step S7: first growth step). In Step S7, the pull-up driver 20 raises and lowers the pull-up shaft 7 under the control of the controller 23 to bring the seed crystal SC into contact with the silicon melt M and then pull up the seed crystal SC.

During or after the growth of the shoulder SM2, the controller 23 determines whether or not the convection direction is likely to reverse if the non-uniform heating mode is switched to the uniform mode while the convection mode is fixed to the clockwise vortex mode, based on the pull-up conditions of the monocrystalline silicon SM and the information for convection reversal determination stored in the storage 22 (Step S8: reversal determination step).

When determining that the convection direction is not likely to reverse by switching the non-uniform heating mode to the uniform mode (step S8: NO), the controller 23 controls the first and second power sources 94A and 94B to switch the non-uniform heating mode to the uniform mode during the growth of the shoulder SM2, or after the growth of the shoulder SM2 and before the growth of the straight body SM3 (Step S9). Then, the controller 23 controls the pull-up driver 20 to grow the straight body SM3 and the tail (Step S10: second growth step).

In this case, the thermal environment in the chamber 2 is axisymmetric with respect to the crucible center axis 3C, and thus the diameter variation of the straight body SM3 and the pull-up speed variation can be inhibited. Furthermore, since the convection direction of the silicon melt M does not reverse even with the heating in the uniform heating mode, variation in oxygen concentration in the straight body SM3 can be inhibited.

On the other hand, when determining that the convection direction is likely to reverse by switching the non-uniform heating mode to the uniform mode (Step S8: YES), the controller 23 grows the straight body SM3 and the tail while maintaining the non-uniform heating mode (Step S10: second growth step).

In this case, since the thermal environment in the chamber 2 is kept non-axisymmetric with respect to the crucible center axis 3C due to the continuation of the non-uniform heating mode, the diameter variation of the straight body SM3 and/or the pull-up speed variation may occur. However, since the convection direction of the silicon melt M does not reverse due to the continuation of the heating in the non-uniform heating mode, the variation in oxygen concentration in the straight body SM3 can be inhibited.

In the above-described production process of the monocrystalline silicon SM, the silicon melt generating step of Step S3 is performed as a first heating and producing process that is performed while the first and second heat generating sections 40A and 40B generate heat with the same heat generation amount in the uniform heating mode. The magnetic field applying step of Step S5, the convection direction checking step of Step S6, and the first growth step of Step S7 are performed as a second heating and producing process that is performed while the first and second heat generating sections 40A and 40B generate heat with heat generation amounts different from each other in the non-uniform heating mode. Further, the second growth step of Step S10 is performed as the first heating and producing process when it is determined in the reversal determination step of Step S8 that the convection direction is not likely to reverse, and is performed as the second heating and producing process when it is determined that the convection direction is likely to reverse.

### Advantage(s) of First Exemplary Embodiment

The monocrystalline silicon production apparatus 1 includes the heater 4 with a hollow cylindrical shape that surrounds the crucible 3 as a structure for heating the crucible 3. The heater 4 includes the first heat generating section 40A and the second heat generating section 40B each having a hollow semi-cylindrical shape. The heater 4 is disposed so that, when the first heat generating section 40A and the second heat generating section 40B generate heat with heat generation amounts different from each other, the heating amounts to the first portion 31A and the second portion 31B of the crucible 3 located on either side with respect to the second vertical virtual plane VF2 are different from each other. In the production process of the monocrystalline silicon SM, the controller 23 of the monocrystalline silicon production apparatus 1 performs the first heating and producing process that is performed while the first and second heat generating sections 40A and 40B generate heat with the same heat generation amount, and the second heating and producing process that is performed while the first and second heat generating sections 40A and 40B generate heat with heat generation amounts different from each other.

Therefore, for instance, by generating the silicon melt M in the uniform heating mode, it is possible to inhibit the silicon material floating in the silicon melt M from flipping over, thereby preventing damage to the quartz crucible 3B. In addition, by applying a horizontal magnetic field to the silicon melt M in the non-uniform heating mode, the convection mode can be fixed to the clockwise vortex mode irrespective of the timing of applying the horizontal magnetic field, thereby inhibiting the variation in oxygen concentration between ingots of the monocrystalline silicon SM. Further, since the variation in oxygen concentration between ingots of the monocrystalline silicon SM can be inhibited, a yield of the monocrystalline silicon SM can be improved, which allows for improvement in energy efficiency, increase in production efficiency, and reduction in waste.

The monocrystalline silicon production apparatus 1 includes the first and second power sources 94A and 94B, the first power supply path 95A through which electric power of the first power source 94A is supplied only to the first heat generating section 40A, and the second power supply path 95B through which electric power of the second power source 94B is supplied only to the second heat generating section 40B.

With this arrangement, the switching can be performed between the uniform heating mode and the non-uniform heating mode, by simply controlling the supply amounts of electric power from the first power source 94A and the second power source 94B.

### Second Exemplary Embodiment

Next, a configuration of a monocrystalline silicon production apparatus according to a second exemplary embodiment of the invention will be described.

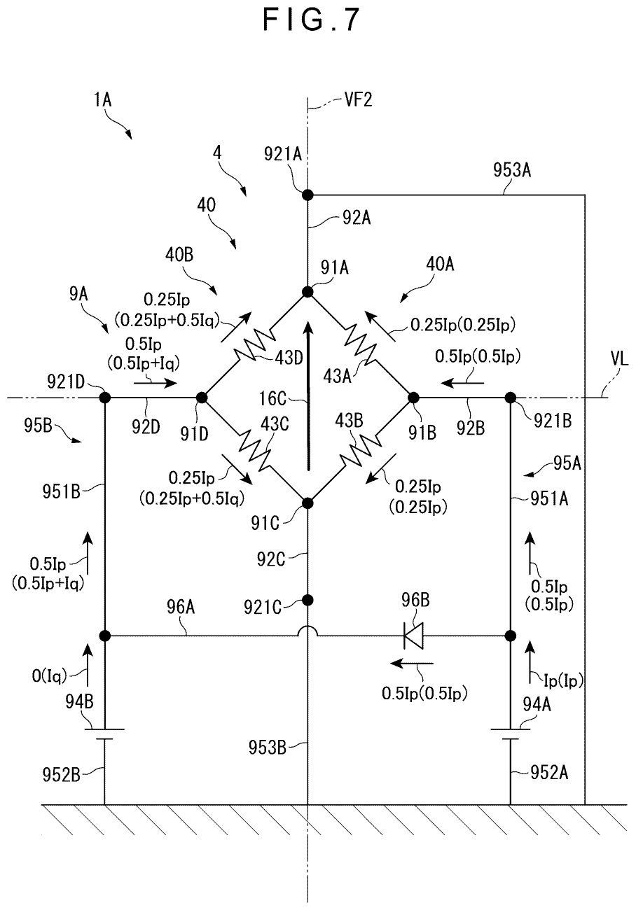

FIG. 7 is an equivalent circuit diagram of a heater and a power supply section.

A monocrystalline silicon production apparatus 1A of the second exemplary embodiment differs from the monocrystalline silicon production apparatus 1 of the first exemplary embodiment in that a controller 23A illustrated in FIG. 5 performs control different from the controller 23 of the first exemplary embodiment, and in that a power supply section 9A illustrated in FIG. 7 has a configuration different from the power supply section 9 of the first exemplary embodiment. The other configurations of the monocrystalline silicon production apparatus 1A are the same as those of the monocrystalline silicon production apparatus 1 of the first exemplary embodiment.

As illustrated in FIG. 7, the power supply section 9A includes, in addition to the same configuration as the power supply section 9 of the first exemplary embodiment, a bypass supply path 96A connecting the first power supply path 95A to the second power supply path 95B, and a flow regulator 96B that is provided in the bypass supply path 96A and supplies electric power only in a direction from the first power supply path 95A to the second power supply path 95B.

The bypass supply path 96A is provided in a form of wiring that connects the first anode wiring 951A to the second anode wiring 951B. The flow regulator 96B is provided in a form of a diode disposed in the middle of the second power supply path 95B.

With the configuration of the heater 4 and the power supply section 9A as illustrated in FIG. 7, when a current with a current value Ip flows from the first power source 94A and no current flows from the second power source 94B, that is, when the electric power is supplied from the first power source 94A and no electric power is supplied from the second power source 94B, a current with a current value 0.25 Ip flows through the first to fourth curve portions 43A to 43D, and the first heat generating section 40A and the second heat generating section 40B generate heat with the same heat generation amount.

On the other hand, when a current with a current value Ip flows from the first power source 94A and a current with a current value Iq flows from the second power source 94B, that is, when the electric power is supplied from the first power source 94A and the second power source 94B, a current with a current value 0.25 Ip flows through the first and second curve portions 43A and 43B, and a current with a current value 0.25 Ip+0.5 Iq flows through the third and fourth curve portions 43C and 43D. Thus, the second heat generating section 40B generates heat with a larger heat generation amount than the first heat generating section 40A.

In FIG. 7, among the codes attached to the arrows indicating the current, the codes outside parentheses represent the current values in the uniform heating mode, while the codes inside the parentheses represent the current values in the non-uniform heating mode.

The controller 23A performs the control similar to that of the controller 23 of the first exemplary embodiment illustrated in FIG. 6 when producing the monocrystalline silicon SM, but the control for heating the crucible 3 in the uniform heating mode and the non-uniform heating mode is different from that of the controller 23.

When heating the crucible 3 in the uniform heating mode, the controller 23A controls the first and second power sources 94A and 94B so that electric power is supplied from the first power source 94A and not from the second power source 94B. When heating the crucible 3 in the non-uniform heating mode, the controller 23A controls the first and second power sources 94A and 94B so that electric power is supplied from the first power source 94A and the second power source 94B.

### Advantage(s) of Second Exemplary Embodiment

The first heat generating section 40A and the second heat generating section 40B have the same heat generation property. The monocrystalline silicon production apparatus 1A includes the first and second power sources 94A and 94B, the first and second power supply paths 95A and 95B, the bypass supply path 96A connecting the first power supply path 95A and the second power supply path 95B, and the flow regulator 96B provided in the bypass supply path 96A and supplying electric power only in the direction from the first power supply path 95A to the second power supply path 95B.

Therefore, the switching can be performed between the uniform heating mode and the non-uniform heating mode, by simply controlling whether or not electric power is supplied from the second power source 94B while a predetermined amount of electric power is supplied from the first power source 94A.

In addition, since the second power source 94B only needs to supply electric power sufficient to produce a difference in heat generation temperature between the first heat generating section 40A and the second heat generating section 40B, a power source with a small capacity is usable as the second power source 94B.

Further, a power source, which is not capable of changing the supply amount of electric power, is usable as the first and second power sources 94A and 94B.

Since variation in oxygen concentration between ingots of the monocrystalline silicon SM can be inhibited, the yield of the monocrystalline silicon SM can be improved, which allows for improvement in energy efficiency, increase in production efficiency, and reduction in waste.

### Modifications

Although the exemplary embodiments of the invention have been described above with reference to the attached drawings, specific configurations are not limited to those in the exemplary embodiments, and various improvements and changes in designs that do not depart from the gist of the invention are included in the invention.

In the first and second exemplary embodiments, the straight body SM3 and the tail may be grown in the non-uniform heating mode without performing Steps S8 and S9.

In the first and second exemplary embodiments, an operator may perform at least one of a switching process of the heating modes in Steps S3, S4, and S9, a starting process of applying a horizontal magnetic field in Step S5, a checking process of the convection mode in Step S6, or a determination process of the convection reversal likelihood in Step S8.

In the first and second exemplary embodiments, as the second heating and producing process, a process is exemplified in which the convection mode is fixed to the clockwise vortex mode by heating the silicon melt M to make the temperature of the left part of the silicon melt M higher than the temperature of the right part thereof. However, another process may be performed in which the convection mode is fixed to the counterclockwise vortex mode by heating the silicon melt M to make the temperature of the right part higher than the temperature of the left part.

In the first and second exemplary embodiments, the heater 4 only needs to be disposed so that the heating amounts applied to the first portion 31A and the second portion 31B of the crucible 3 are different from each other when the first heat generating section 40A and the second heat generating section 40B generate heat with heat generation amounts different from each other. The heater 4 may be disposed in a state rotated clockwise or counterclockwise by an angle less than 45 degrees from the state illustrated in FIG. 2, or in a state rotated clockwise or counterclockwise by an angle more than 45 degrees and less than 90 degrees. In other words, the heater 4 may be disposed so that the second vertical virtual plane VF2 does not coincide with the first vertical virtual plane VF1 illustrated in FIG. 3.

### Example(s)

Examples of the invention will be described next. It should be noted that the invention is not limited to Examples.

### Experiment Conditions

### Comparative

First, the monocrystalline silicon production apparatus 1 according to the first exemplary embodiment was prepared.

Then, the first and second power sources 94A and 94B were controlled to heat the crucible 3 in the uniform heating mode to generate the silicon melt M. Subsequently, a horizontal magnetic field was applied to the silicon melt M while maintaining the uniform heating mode and it was checked that the convection mode was fixed, and then an ingot of the monocrystalline silicon SM having the straight body SM3 with a diameter of 300 mm and a total length of 2,000 mm was grown.

In this case, the output power deviation Δ calculated by the above formula (1) is 0%.

### Examples 1 to 8

In Example 1, the crucible 3 was heated in the uniform heating mode to generate the silicon melt M, and then the first and second power sources 94A and 94B were controlled so that the output power deviation Δ was 3.0%, and the uniform heating mode was switched to the non-uniform heating mode. After the temperature of the silicon melt M was stabilized, a horizontal magnetic field was applied to the silicon melt M and it was checked that the convection mode was fixed, and then an ingot of the monocrystalline silicon SM of the same size as in Comparative 1 was grown.

In Examples 2, 3, 4, 5, 6, 7, and 8, the crucible 3 was heated in the uniform heating mode to generate the silicon melt M, and then ingots of the monocrystalline silicon SM of the same size as in Comparative 1 were grown under the same conditions as Example 1, except that the first and second power sources 94A and 94B were controlled so that the output power deviation Δ was 4.0%, 5.0%, 6.0%, −3.0%, −4.0%, −5.0%, and −6.0%, respectively.

### Evaluation

Ten ingots of the monocrystalline silicon SM were grown in each of Comparative and Examples 1 to 8, and an occurrence rate of the convection mode, the oxygen concentration, and the variation in oxygen concentration were evaluated.

The oxygen concentration was evaluated as follows. First, of each ingot of the monocrystalline silicon SM in Comparative and Examples 1 to 8, a wafer was obtained from the straight body SM3 at a position 1,000 mm below the upper end, and the oxygen concentration of the wafer was measured using FTIR (Fourier transform infrared spectrophotometer). Then, normalization was performed using the average value of the oxygen concentration in the wafers obtained from the ten ingots of the monocrystalline silicon SM in Comparative, and the upper and lower limits of the oxygen concentration in each of Comparative and Examples 1 to 8 were calculated. Further, the difference between the upper and lower limits of the oxygen concentration was calculated as the variation in oxygen concentration.

TABLE 1

| | Output | Occurrence Rate of | | Oxygen | |
|---|---|---|---|---|---|
| | Power | Convection Mode (%) | | Concen- | Variation |
| | Devia- | Counter- | Clock- | tration | in Oxygen |
| | tion | clockwise | wise | (Nomalized | Concen- |
| | Δ(%) | Vortex | Vortex | Value) | tration |
| Comparative | 0 | 50 | 50 | 0.80 to 1.20 | 0.40 |
| Example 1 | 3.0 | 30 | 70 | 0.90 to 1.20 | 0.30 |
| Example 2 | 4.0 | 10 | 90 | 1.15 to 1.20 | 0.25 |
| Example 3 | 5.0 | 0 | 100 | 1.15 to 1.20 | 0.05 |
| Example 4 | 6.0 | 0 | 100 | 1.15 to 1.20 | 0.05 |
| Example 5 | −3.0 | 70 | 30 | 0.80 to 1.10 | 0.30 |
| Example 6 | −4.0 | 90 | 10 | 0.80 to 1.15 | 0.25 |
| Example 7 | −5.0 | 100 | 0 | 0.80 to 0.85 | 0.05 |
| Example 8 | −6.0 | 100 | 0 | 0.80 to 0.85 | 0.05 |

### Occurrence Rate of Convection Mode

In Comparative, the occurrence rate of the counterclockwise vortex mode was 50%, and the clockwise vortex mode and the counterclockwise vortex mode occurred substantially at random.

In contrast, in Examples 1 to 4, the occurrence rate of the clockwise vortex mode exceeded 50%, and the larger the output power deviation Δ, the higher the occurrence rate of the clockwise vortex mode. In particular, in Examples 2 to 4 where the output power deviation Δ was 4.0% or more, the occurrence rate of the clockwise vortex mode was 90% or more, and in Examples 3 and 4 where the output power deviation Δ was 5.0% or more, the occurrence rate of the clockwise vortex mode was 100%. In addition, the similar trend as in Examples 1 to 4 was observable in Examples 5 to 8. In Examples 6 to 8 where the output power deviation Δ was-4.0% or less, the occurrence rate of the counterclockwise vortex mode was 90% or more, and in Examples 7 and 8 where the output power deviation Δ was-5.0% or less, the occurrence rate of the counterclockwise vortex mode was 100%.

The above results could confirm that controlling the first and second power sources 94A and 94B so that an absolute value of the output power deviation Δ was 4.0% or more made it easier to fix the convection mode to one mode irrespective of the timing of applying a horizontal magnetic field. In particular, it could be confirmed that controlling the first and second power sources 94A and 94B so that the absolute value of the output power deviation Δ was 5.0% or more made it possible to fix the convection mode to one mode irrespective of the timing of applying a horizontal magnetic field.

### Variation in Oxygen Concentration

The variation in oxygen concentration in Comparative was 0.40.

In contrast, the variation in oxygen concentration in each of Examples 1 to 8 was 0.30 or less, and the larger the absolute value of the output power deviation Δ, the smaller the variation in oxygen concentration. In particular, in Examples 2 to 4 and 6 to 8 where the absolute value of the output power deviation Δ was 4.0% or more, the variation in oxygen concentration was 0.25 or less, which was nearly half that of Comparative. In Examples 3, 4, 7, and 8 where the absolute value of the output power deviation Δ was 5.0% or more, the variation in oxygen concentration was 0.05, which was extremely small compared to Comparative.

The above results could confirm that the variation in oxygen concentration in the straight body SM3 can be made smaller by controlling the first and second power sources 94A and 94B so that the absolute value of the output power deviation Δ was 4.0% or more, and that, in particular, the variation in oxygen concentration in the straight body SM3 can be made extremely small by controlling the first and second power sources 94A and 94B so that the absolute value of the output power deviation Δ was 5.0% or more.

### INDUSTRIAL APPLICABILITY

Since the production method of monocrystalline silicon and the monocrystalline silicon production apparatus of the invention can inhibit the occurrence of defects during production and the variation in oxygen concentration between ingots of monocrystalline silicon, the yield of the monocrystalline silicon can be improved, which allows for improvement in energy efficiency, increase in production efficiency, and reduction in waste.

### EXPLANATION OF CODES

1, 1A . . . monocrystalline silicon production apparatus, 3 . . . crucible, 3C . . . crucible center axis, 4 . . . heater, 9, 9A . . . power supply section, 16C . . . central magnetic field line, 23, 23A . . . controller, 31A . . . first portion, 31B . . . second portion, 40A . . . first heat generating section, 40B . . . second heat generating section, 94A . . . first power source, 94B . . . second power source, 95A . . . first power supply path, 95B . . . second power supply path, 96A . . . bypass supply path, 96B . . . flow regulator, 401A, 401B . . . highest temperature region, M . . . silicon melt, SM . . . monocrystalline silicon, SM1 . . . neck, SM2 . . . shoulder, SM3 . . . straight body, VF1 . . . first vertical virtual plane, VF2 . . . second vertical virtual plane.

1. A production method of monocrystalline silicon of pulling up the monocrystalline silicon while applying a horizontal magnetic field to a silicon melt, by using a monocrystalline silicon production apparatus,
the monocrystalline silicon production apparatus including
a crucible configured to hold the silicon melt, and
a heater having a hollow cylindrical shape and surrounding the crucible,
the heater including a first heat generating section and a second heat generating section each having a hollow semi-cylindrical shape, the first and second heat generating sections having an identical heat generation property, the heater being disposed so that, when the first and second heat generating sections generate heat with heat generation amounts different from each other, a heating amount of a first portion of the crucible and a heating amount of a second portion of the crucible are different from each other, the first portion and the second portion being located on both sides with respect to a vertical virtual plane that includes a center axis of the crucible and a central magnetic field line of the horizontal magnetic field,
the production method comprising:
performing first heating and producing while the first heat generating section and the second heat generating section generate heat with an identical heat generation amount; and
performing second heating and producing while the first heat generating section and the second heat generating section generate heat with heat generation amounts different from each other.

2. The production method of the monocrystalline silicon according to claim 1, wherein
the monocrystalline silicon production apparatus further includes
a first power source and a second power source,
a first power supply path through which electric power of the first power source is supplied to the first heat generating section, and
a second power supply path through which electric power of the second power source is supplied to the second heat generating section,
the first heating and producing is performed while the first power source and the second power source are controlled to cause the first heat generating section and the second heat generating section to generate heat with an identical heat generation amount, and
the second heating and producing is performed while the first power source and the second power source are controlled to cause the first heat generating section and the second heat generating section to generate heat with heat generation amounts different from each other.

3. The production method of the monocrystalline silicon according to claim 2, wherein
the monocrystalline silicon production apparatus further includes
a bypass supply path connecting the first power supply path to the second power supply path, and
a flow regulator provided in the bypass supply path and configured to supply electric power only in a direction from the first power supply path to the second power supply path,
the first heating and producing is performed while the first power source and the second power source are controlled to supply electric power from the first power source and not from the second power source, and
the second heating and producing is performed while the first power source and the second power source are controlled to supply electric power from the first power source and the second power source.

4. The production method of the monocrystalline silicon according to claim 1, further comprising:
generating the silicon melt by melting a silicon material in the crucible;
starting applying the horizontal magnetic field to the silicon melt;
checking that a convection direction of the silicon melt in a virtual plane is fixed to one direction, the virtual plane being orthogonal to the central magnetic field line;
performing first growing in which a neck and a shoulder are grown by bringing a seed crystal into contact with the silicon melt and then pulling up the seed crystal; and
performing second growing in which a straight body and a tail are grown by pulling up the seed crystal, wherein
the generating the silicon melt and the second growing are performed as the first heating and producing, and
the starting applying the horizontal magnetic field, the checking, and the first growing are performed as the second heating and producing.

5. The production method of the monocrystalline silicon according to claim 1, further comprising:
generating the silicon melt by melting a silicon material in the crucible;
starting applying the horizontal magnetic field to the silicon melt;
checking that a convection direction of the silicon melt in a virtual plane is fixed to one direction, the virtual plane being orthogonal to the central magnetic field line;
performing first growing in which a neck and a shoulder are grown by bringing a seed crystal into contact with the silicon melt and then pulling up the seed crystal;
performing reversal determination; and
performing second growing in which a straight body and a tail are grown by pulling up the seed crystal, wherein
the generating the silicon melt is performed as the first heating and producing,
the starting applying the horizontal magnetic field, the checking, and the first growing are performed as the second heating and producing, and
in the reversal determination as to the second growing to be performed as the first heating and producing based on a pull-up condition of the monocrystalline silicon,
the second growing is performed as the second heating and producing when it is determined that the convection direction is likely to reverse, and
the second growing is performed as the first heating and producing when it is determined that the convection direction is not likely to reverse.

6. The production method of the monocrystalline silicon according to claim 1, wherein
the first heat generating section and the second heat generating section are disposed so that the first and second heat generating sections have respective highest temperature regions overlapping a horizontal virtual line in planar view, the horizontal virtual line being orthogonal to the vertical virtual plane and including the center axis of the crucible.

7. A monocrystalline silicon production apparatus configured to pull up a monocrystalline silicon while applying a horizontal magnetic field to a silicon melt, the apparatus comprising:
a crucible configured to hold the silicon melt;
a heater having a hollow cylindrical shape and surrounding the crucible; and
a power supply section configured to supply electric power to the heater, wherein
the heater includes a first heat generating section and a second heat generating section each having a hollow semi-cylindrical shape, the first and second heat generating sections having an identical heat generation property, and
the power supply section includes
a first power source and a second power source,
a first power supply path through which electric power of the first power source is supplied to the first heat generating section, and
a second power supply path through which electric power of the second power source is supplied to the second heat generating section.

8. The monocrystalline silicon production apparatus according to claim 7, wherein
the power supply section further includes
a bypass supply path connecting the first power supply path to the second power supply path, and
a flow regulator provided in the bypass supply path and configured to supply electric power only in a direction from the first power supply path to the second power supply path.

9. The monocrystalline silicon production apparatus according to claim 7, further comprising:
a controller configured to control producing, the monocrystalline silicon being pulled up in the producing, wherein
the producing includes
performing first heating and producing while the first power source and the second power source are controlled to cause the first heat generating section and the second heat generating section to generate heat with an identical heat generation amount, and
performing second heating and producing while the first power source and the second power source are controlled to cause the first heat generating section and the second heat generating section to generate heat with heat generation amounts different from each other.

10. The monocrystalline silicon production apparatus according to claim 8, further comprising:
a controller configured to control producing, the monocrystalline silicon being pulled up in the producing, wherein
the producing includes
performing first heating and producing while the first power source and the second power source are controlled to supply electric power from the first power source and not from the second power source, and
performing second heating and producing while the first power source and the second power source are controlled to supply electric power from the first power source and the second power source.

11. The monocrystalline silicon production apparatus according to claim 9, wherein
the producing further includes
generating the silicon melt by melting a silicon material in the crucible,
starting applying the horizontal magnetic field to the silicon melt,
checking that a convection direction of the silicon melt in a virtual plane is fixed to one direction, the virtual plane being orthogonal to a central magnetic field line of the horizontal magnetic field,
performing first growing in which a neck and a shoulder are grown by bringing a seed crystal into contact with the silicon melt and then pulling up the seed crystal, and
performing second growing in which a straight body and a tail are grown by pulling up the seed crystal, and
the controller is configured
to perform the generating the silicon melt and the second growing as the first heating and producing, and
to perform the starting applying the horizontal magnetic field, the checking, and the first growing as the second heating and producing.

12. The monocrystalline silicon production apparatus according to claim 9, wherein
the producing further includes
generating the silicon melt by melting a silicon material in the crucible,
starting applying the horizontal magnetic field to the silicon melt,
checking that a convection direction of the silicon melt in a virtual plane is fixed to one direction, the virtual plane being orthogonal to a central magnetic field line of the horizontal magnetic field,
performing first growing in which a neck and a shoulder are grown by bringing a seed crystal into contact with the silicon melt and then pulling up the seed crystal,
performing reversal determination, and
performing second growing in which a straight body and a tail are grown by pulling up the seed crystal, and
the controller is configured
to perform the generating the silicon melt as the first heating and producing,
to perform the starting applying the horizontal magnetic field, the checking, and the first growing as the second heating and producing, and
in the reversal determination as to the second growing to be performed as the first heating and producing based on a pull-up condition of the monocrystalline silicon,
to perform the second growing as the second heating and producing when it is determined that the convection direction is likely to reverse, and
to perform the second growing as the first heating and producing when it is determined that the convection direction is not likely to reverse.

13. The monocrystalline silicon production apparatus according to claim 7, wherein
the first heat generating section and the second heat generating section are disposed so that the first and second heat generating sections have respective highest temperature regions overlapping a horizontal virtual line in planar view, the horizontal virtual line being orthogonal to a vertical virtual plane and including a center axis of the crucible, the vertical virtual plane including the center axis of the crucible and a central magnetic field line of the horizontal magnetic field.

14. The monocrystalline silicon production apparatus according to claim 10, wherein
the producing further includes
generating the silicon melt by melting a silicon material in the crucible,
starting applying the horizontal magnetic field to the silicon melt,
checking that a convection direction of the silicon melt in a virtual plane is fixed to one direction, the virtual plane being orthogonal to a central magnetic field line of the horizontal magnetic field,
performing first growing in which a neck and a shoulder are grown by bringing a seed crystal into contact with the silicon melt and then pulling up the seed crystal, and
performing second growing in which a straight body and a tail are grown by pulling up the seed crystal, and
the controller is configured
to perform the generating the silicon melt and the second growing as the first heating and producing, and
to perform the starting applying the horizontal magnetic field, the checking, and the first growing as the second heating and producing.

15. The monocrystalline silicon production apparatus according to claim 10, wherein
the producing further includes
generating the silicon melt by melting a silicon material in the crucible,
starting applying the horizontal magnetic field to the silicon melt,
checking that a convection direction of the silicon melt in a virtual plane is fixed to one direction, the virtual plane being orthogonal to a central magnetic field line of the horizontal magnetic field,
performing first growing in which a neck and a shoulder are grown by bringing a seed crystal into contact with the silicon melt and then pulling up the seed crystal,
performing reversal determination, and
performing second growing in which a straight body and a tail are grown by pulling up the seed crystal, and
the controller is configured
to perform the generating the silicon melt as the first heating and producing,
to perform the starting applying the horizontal magnetic field, the checking, and the first growing as the second heating and producing, and
in the reversal determination as to the second growing to be performed as the first heating and producing based on a pull-up condition of the monocrystalline silicon,
to perform the second growing as the second heating and producing when it is determined that the convection direction is likely to reverse, and
to perform the second growing as the first heating and producing when it is determined that the convection direction is not likely to reverse.
